(19) United States
(12) Patent Application Publication
(10) Pub. No.: US 2010/0144122 A1
(43) Pub. Date: Jun. 10, 2010

(54) Hybrid chemical vapor deposition process combining hot-wire cvd and plasma-enhanced cvd

(76) Inventors: Xinmin Cao, Sylvania, OH (US); Xunming Deng, Sylvania, OH (US); Aarohi Vijh, Sylvania, OH (US)

Correspondence Address: Emch, Schaffer, Schaub & Porcello, Co., L.P.A, P.O. Box 916, Toledo, OH, 43697-0916, US

(21) Appl. No.: 12/452,544

(22) PCT Filed: Jul. 7, 2008
(86) PCT No.: PCT/US2008/069358

§ 371 Date: Jan. 6, 2010

Related U.S. Application Data
(60) Provisional application No. 60/958,525, filed on Jul. 7, 2007.

(51) Int. Cl. H01L 21/365; C23C 16/00

(52) U.S. Cl. 438/478; 118/723 R; 118/723 VE; 118/723 E; 257/E21.463

(57) ABSTRACT

Hybrid chemical vapor deposition systems for depositing a semiconductor-containing thin film over a substrate comprise a reaction space, a substrate support member configured to permit movement of a substrate in a longitudinal direction and a plasma-generating apparatus disposed in the reaction space and configured to form plasma-excited species of a vapor phase chemical. The systems further comprise a hot wire unit disposed in the reaction space and configured to heat and decompose a vapor phase chemical. The hot wire unit can be a filament. The systems can further comprise an additional reaction space proximate the reaction space. The additional reaction space can comprise a plasma-generating apparatus configured to form plasma-excited species of a vapor phase chemical and a hot wire unit configured to heat and decompose a vapor phase chemical.

This application claims the benefit of priority to U.S. Provisional Application No. 60/958,525, filed Jul. 7, 2007, which is entirely incorporated by reference herein.

### FIELD OF THE INVENTION

The invention relates to new thin film deposition methods and apparatuses for producing high quality semiconductor thin films. More particularly, the invention relates to apparatuses and methods that employ hot-wire chemical vapor deposition (HWCVD) and plasma-enhanced chemical vapor deposition (PECVD) for producing high quality semiconductor thin films.

### BACKGROUND OF THE INVENTION

Thin film semiconductors are useful in a variety of electronic devices, such as photovoltaic (PV) cells, liquid crystal displays and various components of electronics devices. Amorphous silicon is particularly useful in PV applications.

One method for forming thin film semiconductors, such as amorphous silicon or microcrystalline silicon, is to deposit a thin film onto a suitable substrate using a chemical vapor deposition (CVD) process. In CVD, one or more gas-phase (or vapor-phase) chemicals are brought in contact with a substrate surface to form a film (or thin film) comprising constituents of the one or more gas-phase chemicals.

One of the most commonly used CVD methods to deposit amorphous or microcrystalline silicon is plasma-enhanced chemical vapor deposition (PECVD). In PECVD, application (or coupling) of energy to a vapor phase chemical is used form plasma-excited species of the vapor phase chemical, which are brought in contact with a substrate surface to form a thin film. However, PECVD forms thin films at a rate of up to several angstroms per second (Å/s), leading to low throughput, which makes batch PECVD apparatuses and methods impractical for large-scale commercial use. At such low rates, longer deposition times are required to provide a thin film with a desired (or predetermined) thickness, leading to high manufacturing costs. Further, long deposition times can lead to poor film quality in view of contamination form the background gas.

There are various methods available in the art for providing high, commercial throughput of silicon-containing thin films. An apparatus-based solution involves using continuous deposition. For example, U.S. Pat. No. 4,410,558 to Izu et al. (“Izu”), which is entirely incorporated herein by reference, teaches a continuous, roll-to-roll deposition method for forming a thin film over a substrate. Izu teaches the roll-to-roll production of solar cells by the glow discharge (plasma) deposition of layers of varying electrical characteristics, which is achieved by advancing a substrate through a succession of deposition chambers. Each of the chambers is dedicated to a specific material type deposition. As another example, U.S. Pat. No. 6,186,090 to Dotter, II et al. (“Dotter”), which is entirely incorporated herein by reference, teaches depositing at least two different layers of thin film material onto a substrate by two different vacuum deposition processes. Dotter also teaches a linear applicator for using PECVD to uniformly deposit a thin film of material over an elongated substrate. However, a limitation of Izu and Dotter is that, although roll-to-roll deposition offers improvements in throughputs relative to batch plasma-based methods, the improvements are of limited impact, especially in the case of semiconductor manufacturing, such as solar cell manufacturing, where the simultaneous attainment of specific material qualities of the deposited layers and high speed of manufacturing by any method has heretofore been difficult. Further, roll-to-roll plasma-based deposition systems can be expensive, leading to increases in manufacturing costs.

An alternative to PECVD is hot-wire chemical vapor deposition (HWCVD). In HWCVD, a thin foil or metal wire filament is used to thermally excite a vapor phase chemical. The filament, which can be formed of, e.g., tungsten, tantalum, or molybdenum, is heated to a high temperature. A gas is brought near or in contact with the hot filament. The hot filament breaks down the gas into various constituents, which are subsequently deposited on a substrate. HWCVD enables thin film deposition at high rates, up to an exceeding 100 Å/s.

There are various examples of HWCVD systems (or apparatuses) and methods available in the art. U.S. Pat. Nos. 5,397,737, 5,776,819, 6,124,186, 6,214,706, 6,251,183, which are entirely incorporated herein by reference, teach depositing films using hot-wire processes. These methods provide deposition at rates of less than 50 Å/sec. Ichikawa, M., Takeshita, J., Yamada, A, and Kongai, M., Japan J. Appl. Phys. 38, L24 (1999), and Yu, S., Gulari, E., and Kanicki, J., Appl. Phys. Lett., 68, 2681 (1996), which are entirely incorporated herein by reference, teach deposition of polycrystalline silicon and/or microcrystalline silicon films using a hot-filament.

The HWCVD systems and methods available in the art have various limitations. For example, due to the lack of controllability over the concentration of radicals, these methods fail to provide amorphous silicon-based solar cells with thin film quality comparable to state-of-the-art solar cells produced using PECVD methods. This is due, at least in part, to the lack of low energy bombardment by reactive species during thin film deposition and the lack of control over the distribution of reactive species during deposition. For example, during the deposition of amorphous silicon, there are significant amounts of Si, SiH, SiH₂, and SiH₃ species in the mixture, while the species responsible for high-quality film is believed to be SiH₃. Poor thin film quality is due at least in part to HWCVD filament turn-on (or heat up) and turn-off (or cool down) at the start and finish of thin film deposition, which is derived from prior art batch deposition chambers. For instance, during filament turn-on, various vapor phase contaminants are out gassed from the HWCVD filament, which adsorb on a substrate surface and get incorporated into a growing thin film. At the completion of thin film deposition, the filament needs to be turned off before the substrate can be removed from the deposition chamber. The time period between the point at which the filament is turned off and the substrate is removed from the deposition chamber can lead to the incorporation of contaminants into the thin film, leading to low thin film quality. Low thin film quality is due at least in part to poor interfaces between thin films and underlying substrates.

Systems employing HWCVD and PECVD are available in the art. For example, U.S. Pat. Nos. 6,755,151 and 6,638,839 to Deng et al. (“Deng”), which are entirely incorporated herein by reference, teach a thin film deposition method using a vacuum confinement cup that employs a dense hot filament, RF electrodes and multiple gas inlets. A limitation of Deng is that because Deng uses a batch system, the low throughputs of Deng are not suited for large-scale commercial use. Another limitation of Deng's batch deposition method is that thin film contamination during hot-wire filament turn-on and turn-off leads to poor film quality.

Accordingly, there is a need for CVD apparatuses and methods that provide improved deposition rates (and commercially applicable throughputs) and high quality films over prior art apparatuses and methods. There is a further need for improved methods to produce amorphous silicon and microcrystalline silicon films having improved properties over prior art methods.

### SUMMARY OF THE INVENTION

The invention provides systems and methods for depositing semiconductor-containing thin films. Such systems may include one or more reaction spaces, each reaction space having one or more plasma-generating apparatuses configured for PECVD and one or more hot-wire filaments configured for HWCVD. A substrate on which deposition is desired may be moved at a predetermined rate during thin films deposition. The invention may be applied as a standalone system or method, or as part of a larger fabrication system. It shall be understood that different aspects and embodiments of the invention can be appreciated individually, collectively, or in combination with each other.

An aspect of the invention provides a system for depositing a thin film over a substrate. The system comprises a reaction space, a substrate support member configured to permit movement of a substrate in a longitudinal direction and a plasma-generating apparatus disposed in the reaction space and configured to form plasma-excited species of a vapor phase chemical. The system further comprises a hot-wire (also “hot wire” herein) unit disposed in the reaction space and configured to heat and decompose a vapor phase chemical. The hot-wire unit can be a filament. In one embodiment of the invention, the system further comprises an additional reaction space proximate the reaction space. The additional reaction space can comprise a plasma-generating apparatus configured to form plasma-excited species of a vapor phase chemical and a hot-wire unit configured to heat and decompose a vapor phase chemical. The system may further comprise at least one of a payout chamber or a take-up chamber to transport the substrate in a longitudinal direction or other direction during thin film deposition.

Another embodiment of the invention provides a thin film deposition chamber comprising a hot wire filament capable of being heated to 1500° C. or higher, and an electrode to form and maintain a plasma for thin film deposition. The thin film deposition chamber further comprises a substrate support member configured to permit movement of a substrate in a longitudinal direction.

Yet another embodiment of the invention provides a thin film deposition chamber comprising a plurality of plasma electrodes; a plurality of filaments configured to heat and decompose a vapor phase chemical; and a roller to permit movement of a substrate in a longitudinal direction. In a preferable embodiment of the invention, the plurality of plasma electrodes and the plurality of filaments can be arranged in an alternating configuration.

Still another embodiment of the invention provides an apparatus for forming a thin film on a substrate. The apparatus comprises a first hot wire unit and a second hot wire unit configured to form thermally-excited species of a vapor phase chemical; and a first plasma-generating member (or apparatus) configured to form plasma-excited species of a vapor phase chemical.

Another aspect of the invention provides methods for depositing one or more layers of a semiconductor-containing material on a substrate. A preferable method comprises providing the substrate in a reaction space. Next, a gas (or vapor phase chemical) is provided in the reaction space, the gas including a semiconductor-containing chemical. Plasma-excited species and thermally-excited species of the semiconductor-containing chemical are formed in the reaction space. The substrate is contacted with the plasma-excited species and the thermally-excited species of the semiconductor-containing chemical. In a preferable embodiment of the invention, the substrate is contacted with the plasma-excited species and the thermally-excited species of the semiconductor-containing chemical while it is moved from a first position to a second position in the reaction space. In some embodiments of the invention, the semiconductor-containing chemical may be provided in the reaction space with the aid of a carrier gas such as hydrogen (H₂).

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments of the invention. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The features and advantages of the invention may be further explained by reference to the following detailed description and accompanying drawings that sets forth illustrative embodiments of the invention.

FIG. 1 is a schematic cross-sectional side view of a hybrid CVD reaction chamber including a plasma electrode and a filament.

FIG. 2 is a schematic cross-sectional side view of a hybrid CVD system including plasma electrodes and filaments. The illustrated hybrid CVD system is configured for simultaneous deposition on two substrates.

FIG. 3 is a process flow diagram for forming a semiconductor-containing thin film.

FIG. 4 is a process flow diagram for forming an amorphous silicon thin film using silane.

FIG. 5 is a schematic cross-sectional side view of a hybrid CVD reaction chamber with a plasma-generating apparatus disposed above a plurality of filaments.

FIG. 6 is a schematic cross-sectional side view of a hybrid CVD reaction chamber having combined hot wire unit and plasma-generating apparatus.

FIG. 7 is a schematic cross-sectional side view of a hybrid CVD system having a plurality of reaction chambers.

### DETAILED DESCRIPTION OF THE INVENTION

While various embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The invention provides hybrid chemical vapor deposition (HCVD) apparatuses and methods for forming high quality silicon-containing films (or thin films) at high throughputs that are applicable in commercial settings. An embodiment of a hybrid CVD apparatus comprises one or more plasma-generating apparatuses configured to form plasma-excited species of a vapor phase chemical and one or more hot wire units configured to form thermally-excited species of a vapor phase chemical. In one embodiment of the invention, a substrate is directed through one or more reaction spaces in a roll-to-roll (continuous) fashion while plasma-excited and thermally-excited species of a vapor phase chemical are brought in contact with the substrate.

The hybrid CVD apparatuses and methods of various embodiments of the invention enable formation of silicon thin films that can be used in various applications. For example, methods and apparatuses of embodiments of the invention can be used to form an amorphous silicon thin film that can serve as the absorber layer of a photovoltaic device.

The hybrid chemical vapor deposition apparatuses and methods of various embodiments of the invention exploit the advantages of hot wire CVD (HWCVD), plasma-enhanced CVD (PECVD) and roll-to-roll deposition systems to create a process that is suitable for forming high quality amorphous silicon (a-Si), micro- or nanocrystalline silicon (μc-Si or nc-Si), and polycrystalline silicon (poly-Si) solar cells at ultrahigh rates up to and exceeding 100 Å/s. Embodiments of the invention provide for forming plasma-excited and thermally-excited vapor phase species of a silicon-containing chemical (e.g., silane) and the utilization of continuous roll-to-roll fabrication techniques in order to avoid problems associated with filament turn-on and turn-off.

An advantage of hot wire CVD is forming atomic H and decomposing a silicon-containing vapor phase chemical efficiently, and providing for thin films at high rates and at low temperatures. An advantage of plasma-enhanced CVD is low energy ion bombardment that can aid in hydrogen elimination from a thin film and nanocrystalline grain growth. An advantage of roll-to-roll deposition is the avoidance of filament turn-on and turn-off, which is a characteristic of batch deposition systems. Combining HWCVD and PECVD into a hybrid CVD (H-CVD) process that utilizes roll-to-roll deposition enables separate control of deposition rate and thin film quality, allowing production of high-quality materials.

A plasma-generating apparatus may be a wire, foil, or plate in electrical contact with a power supply, such as a radio frequency (RF) or very high frequency (VHF) power supply. A hot wire unit may be an electrically resistive wire, foil, or plate in electrical contact with a power supply, such as a direct current (DC) power supply. The plasma-generating apparatus and the hot wire unit may be adjacent one another in the same reaction space. The plasma-generating apparatus may include a gas distribution unit for providing a vapor phase chemical into the reaction space. In some cases, a reaction space may include a single plasma-generating apparatus disposed above one or more hot wire filaments. The plasma-generating apparatus in such a case may be a plasma showerhead (“showerhead”) configured to provide a vapor phase chemical into a reaction space. Examples of showerheads that can be used in such a case are provided in U.S. Pat. Nos. 5,252,178, 5,614,055 and 5,595,606, which are entirely incorporated herein by reference.

Hybrid CVD systems of embodiments of the invention can include a computer system for controlling application of power for plasma generation and controlling the application of power for forming thermally-excited species of a vapor phase chemical. Hybrid CVD systems of embodiments may also include one or more vacuum pumps for maintaining a vacuum in one or more reaction spaces of a hybrid CVD system. Vacuum systems may include a mechanical pump, a turbomolecular pump, a diffusion pump and an ion pump. Exemplary vacuum systems may include an ion pump that is backed by a turbomolecular pump, which can be backed by a mechanical pump. During deposition the ion pump may be shut off.

### Definitions

“Plasma-excited species” refers to radicals, ions or other excited species generated via application (or coupling) of energy to a vapor phase chemical. Energy may be applied via a variety of methods, such as, e.g., induction, ultraviolet radiation, microwaves and capacitive coupling. The plasma generator may be a direct plasma generator (i.e., in situ or direct plasma generation) or a remote plasma generator (i.e., ex situ or remote plasma generation). In the absence of coupling energy, plasma generation is terminated. Plasma-excited species include, without limitation, radicals and ions. For example, plasma-excited species of silane (SiH₄) can include radicals, cations and anions of SiH₄ and its constituents, such as, e.g., SiH₃ radical, SiH₃⁺, SiH₂²⁺. For in situ plasma generation, plasma-excited species of a particular vapor phase chemical (e.g., SiH₄) are formed in a reaction space comprising a substrate to be processed. For remote plasma generation, plasma-excited species are formed external to the reaction space comprising the substrate.

“Thermally-excited species” refers to atoms and molecules generated via application of thermal energy to a vapor phase chemical. Thermally-excited species of a vapor phase chemical can include constituents of the vapor phase chemical. As an example, thermally-excited species of silane (SiH₄) can include the constituents of SiH₄, such as, e.g., SiH, SiH₂ and SiH₃. Thermally-excited species of a vapor phase chemical can include electrically neutral constituents of the vapor phase chemical. Thermally-excited species of a vapor phase chemical can be formed by bringing a vapor phase chemical near or in contact with a hot wire or filament, which can dissociate the vapor phase chemical.

“Reaction space” refers to a reactor or reaction chamber, or an arbitrarily defined volume therein, in which conditions can be adjusted to effect film or thin film growth on a substrate by a vapor phase deposition technique, such as CVD. A reaction space can be, for example, a reaction chamber or a plurality of reaction chambers where deposition on a single substrate or multiple substrates can take place. A reaction space can be configured for generation of thermally-excited and plasma-excited species of a vapor phase chemical, either in situ or remote.

“N-type” and “p-type” refer to semiconductor-containing layers that are chemically-doped (“doped”) n-type or p-type, respectively. N-type doping may be achieved with an n-type chemical dopant (“dopant”), such as, e.g., PH₃; p-type doping may be achieved using a p-type chemical dopant, such as, e.g., BF₃.

“Adsorption” refers to chemical attachment of atoms or molecules to a surface.

“Substrate” refers to any workpiece on which deposition is desired. Typical substrates include, without limitation, silicon, silica, coated silicon, metal foil and plastic foil.

“Surface” refers to a boundary between a reaction space and a feature of a substrate.

Reference will now be made to the figures, wherein like numerals refer to like parts throughout. It will be appreciated that the figures are not necessarily drawn to scale.

In one aspect of the invention, a hybrid CVD reaction chamber for forming a silicon-containing thin film (e.g., amorphous silicon thin film) on a substrate comprises one or more plasma-generating apparatuses (also “plasma-generating members” and “plasma-generating units” herein) and one or more hot wire units (also “hot wire members” and “hot wire apparatuses” herein).

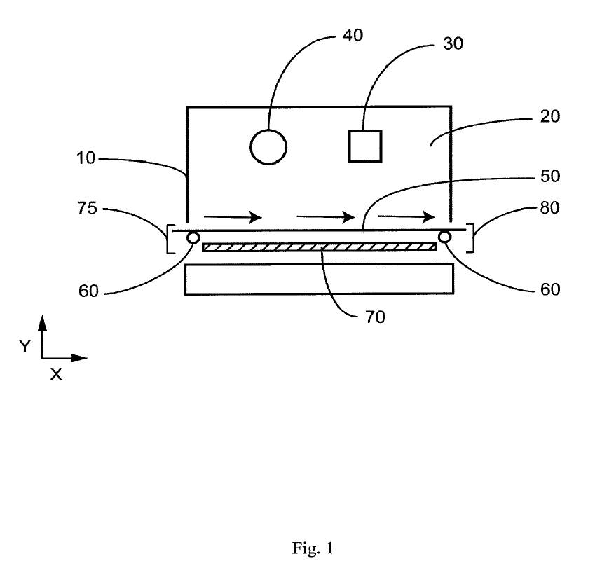

FIG. 1 shows a hybrid CVD reaction chamber 10, in accordance with an embodiment of the invention. The reaction chamber 10 comprises a reaction space 20, a plasma-generating apparatus 30 for forming plasma-excited species of a vapor phase chemical, in combining with a hot wire unit 40 for forming thermally-excited species of a vapor phase chemical. The substrate 50 of the illustrated embodiment is disposed below the plasma-generating apparatus 30 and the hot wire unit 40. Substrate support members 60 hold the substrate 50 in a stable plane while permitting longitudinal movement of the substrate 50. The substrate 50 may be a single block, or a roll of substrate or a coil of substrate as part of a roll-to-roll mechanism. In one embodiment, the substrate support members 60 may be rollers (e.g., magnetic rollers). In another embodiment, the substrate support members 60 may include sprockets for providing longitudinal movement of the substrate 50 during thin film deposition. The substrate support members 60 may be attached to one or more motors, such as, e.g., electrical motors, to aid in the longitudinal movement of the substrate 50. In an embodiment of the invention, the substrate support members 60 permit movement (or transport) of the substrate 50. In a preferable embodiment of the invention, the substrate support members 60 permit movement of the substrate 50 during thin film deposition (also “deposition” herein).

The plasma-generating apparatus 30 may be wire, plate, tube, or electrode in electrical communication with a power supply, such as VHF power supply. In such a case, the substrate 50 is in electrical communication with ground (i.e., the substrate 50 is “grounded”). Alternatively, the substrate 50 may be in electrical communication with a power supply while the plasma-generating apparatus 30 is grounded.

Vapor phase chemicals (e.g., SiH₄) may be provided into the reaction space 20 through the plasma-generating apparatus 30. For example, if the plasma-generating apparatus 30 comprises a tube, vapor phase chemicals may be provided into the reaction space 20 through the tube. However, a vapor phase chemical may be provided into the reaction space via a tube or a showerhead (not shown) that is electrically isolated from the plasma-generating apparatus 30 and filament 40. For example, the reaction chamber 10 may comprise a gas inlet port (not shown) above the plasma-generating apparatus 30 and filament 40. As another example, a vapor phase chemical may be provided into the reaction space 20 via a substrate inlet port (not shown).

The hot wire unit 40 may be a filament formed of any electrically resistive material, such as, e.g., tungsten, tantalum, or molybdenum, in any kind of shapes, such as, e.g., wire, rod, tube, or strip. In some cases the hot wire unit 40 may be formed of a plurality of metals. In such a case, the hot wire 40 would be formed of a metal alloy. During heating the hot wire 40 can degrade due to the evaporative loss of metal atoms from the filament and formation of a metal silicide if a vapor phase chemical comprising silicon is used during deposition. In such a case, during deposition one or more filaments of the hot wire unit 40 can be replenished either continually or per a predetermined schedule. In one embodiment, the one or more filaments of the hot wire unit 40 are connected to a wire feeding mechanism that directs a fresh supply of filament into the reaction space 20 during thin film deposition. During deposition, thermally-excited species of a vapor phase chemical are formed by heating the one or more filaments of the hot wire unit 40 to a temperature greater than or equal to about 1000° C., or greater than or equal to about 1500° C., or greater than or equal to about 1800° C.

With continued reference to FIG. 1, the distance between the plasma-generating apparatus 30 and the substrate 50 is approximately the same as the distance between the hot wire 40 and the substrate 50. However, it will be appreciated that the distances may be different. For example, the plasma-generating apparatus 30 may be a plate or showerhead disposed above the hot wire 40 and away from the substrate 50.

A vapor phase chemical may be introduced into the reaction space 20 via an inlet port, and any excess (or unreacted) vapor phase chemical may be pumped out through an outlet port. It will be appreciated that thin film deposition commences when a vapor phase chemical is introduced into the reaction space 20, wherein the vapor phase chemical comprises a precursor of a thin film to be formed on the substrate 50.

In one embodiment of the invention, the substrate 50 is provided into the reaction space 20 via a substrate inlet port 75 and taken out of the reaction space via a substrate outlet port 80. The substrate inlet port 75 and outlet port 80 may also serve as the inlet and outlet ports for the vapor phase chemical. In one embodiment, the substrate 50 can provided into the reaction space and moved during deposition in the direction of the illustrated arrows. The substrate may be provided into the reaction space 20 in a continuous fashion such that a portion of the substrate 50 has a predetermined residence time in the reaction space 20 that is a function of the rate at which the portion of the substrate 50 is directed into the reaction space 20 and the size of the reaction space 20. For example, the substrate 50 may be a substrate roll that is part of a roll-to-roll system. The substrate 50 in such a case may be directed into the reaction space 20 at a rate of 15 feet/minute, for example.

The reaction chamber 10 may include a heater (also “heating element” herein) 70 near the substrate 50. The heater 70 may be configured to heat the substrate 50 during thin film deposition. The heater 70 may be configured to provide heat via radiative heating or conductive heating. If radiative heating is employed, the heater 70 may be a filament (e.g., tungsten, tantalum, or molybdenum filament), a heated plate, or a halogen lamp in close proximity to a bottom surface of the substrate 50. The heater 70 may be a heating apparatus comprising a plurality of heating units, such as a heating apparatus comprising a plurality of heating filaments evenly dispersed below the substrate 50.

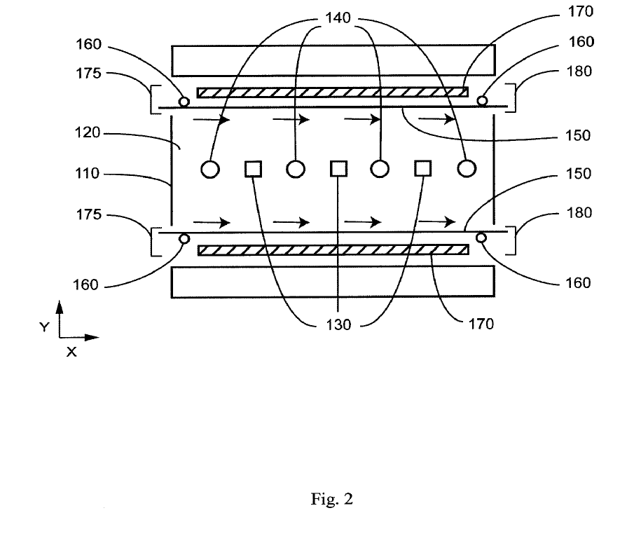

FIG. 2 illustrates a reaction chamber 110, in accordance with an embodiment of the invention. The reaction chamber 110 comprises a reaction space 120, a plurality of plasma-generating apparatuses 130 for forming plasma-excited species of a vapor phase chemical, a plurality of hot wire units 140 for forming thermally-excited species of a vapor phase chemical, two substrates 150, substrate support members 160 and heating members 170. The plasma-generating apparatuses 130 and the hot wire units 140 are disposed in an alternating configuration along an ‘x’ axis and vertically aligned along a ‘y’ axis that is orthogonal to the x axis.

The plasma-generating apparatuses 130 may be wires, plates, tubes, or electrodes in electrical communication with a power supply, such as VHF power supply. In such a case, the substrates 150 can be grounded. Alternatively, the substrates 150 may be in electrical communication with a power supply and the plasma-generating apparatuses 130 may be grounded. Vapor phase chemicals (e.g., SiH₄) may be provided into the reaction space 120 through the plasma-generating apparatuses 130. In the illustrated embodiment, the plasma-generating apparatuses 130 comprise plasma tube arrays (cathode or anode) with gas shower inlets.

Each of the hot wire units 140 may include a filament or filament array. The filaments may be formed of any electrically resistive material, such as, e.g., tungsten, tantalum, or molybdenum, or a plurality of metals, such as a metal alloy, in any kind of shapes, such as, e.g., wire, rod, tube, or strip. If the hot wire units 140 comprise filaments, the filaments may be replenished, as described above in the context of FIG. 1.

Each of the substrates 150 may be a single block, or a roll of substrate or a coil of substrate as part of a roll-to-roll mechanism. Each of the substrates 150 can enter the reaction space 120 through a substrate inlet port 175 and leave the reaction space through a substrate outlet port 180. Substrate support members 160 can hold the substrates 150 in a stable plane while permitting longitudinal movement. In one embodiment, the substrate support members 160 can be rollers. In another embodiment, the substrate support members 160 can include sprockets and be connected to one or more motors (e.g., electrical motors) for providing lateral (or longitudinal) movement (or transport) of the substrates 150. While the substrate support members 160 as illustrated are disposed in the reaction space 120, it will be appreciated that the substrate support members 160 need not be disposed in the reaction space 120.

With continued reference to FIG. 2, the distance between the plasma-generating apparatuses 130 and the substrates 150 is approximately the same as the distance between the hot wire units 140 and the substrates 150. However, it will be appreciated that the distances may be different. The number of hot wire units may be the same or different from the number of plasma-generating apparatuses 130, and the plasma-generating apparatuses 130 and the hot wire units 140 may or may not be disposed in an alternating configuration. Additionally, while a plurality of plasma-generating apparatuses 130 and filaments 140 are shown, it will be appreciated that the reaction chamber 110 may include a single plasma-generating apparatus and a plurality of filaments or a single filament and a plurality of plasma-generating apparatus. For example, the reaction chamber 110 may include a single plasma-generating apparatus 130 at the center of the reaction space 120. The single plasma-generating apparatus may be a plate or showerhead disposed at the center of the reaction space 120 and spanning the length of the reaction space 120 along the x-axis, and the filaments 140 may be evenly dispersed along the x-axis.

A vapor phase chemical may be introduced via an inlet and pumped out through an outlet. In one embodiment, the substrate inlet port 175 and outlet port 180 may also serve as inlet and outlet ports for the vapor phase chemical. It will be appreciated that thin film deposition commences when a vapor phase chemical is introduced into the reaction space 120, wherein the vapor phase chemical comprises a precursor of a thin film to be formed on the substrates 150.

In another aspect of the invention, a method for forming a layer of a semiconductor-containing material is provided. In embodiments of the invention, the layer of the semiconductor-containing material is a semiconductor-containing thin film. In one embodiment of the invention, a method for forming a semiconductor-containing thin film comprises bringing a substrate in contact with plasma-excited and thermally-excited species of a semiconductor-containing vapor phase chemical (also “semiconductor-containing gas” herein).

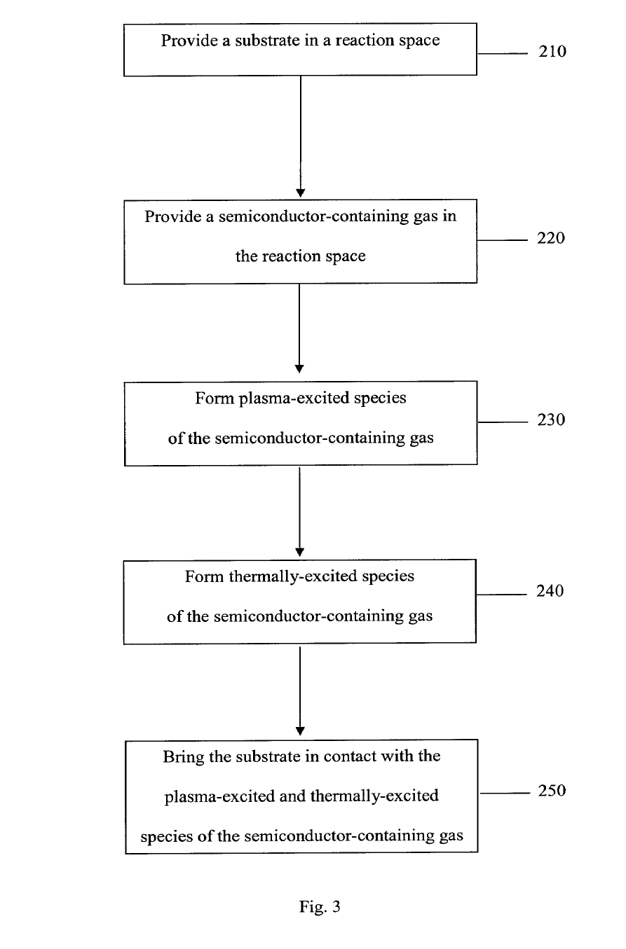

FIG. 3 illustrates a process flow diagram for forming a semiconductor-containing thin film, in accordance with an embodiment of the invention. A substrate upon which deposition is desired is provided 210 in a reaction space of a reaction chamber. In a preferable embodiment of the invention, the substrate is continuously provided into the reaction space. In an embodiment of the invention, the substrate is provided in a roll-to-roll fashion, as described above. Next, a semiconductor-containing gas is provided 220 into the reaction space. Next, plasma-excited species 230 and thermally-excited species 240 of the semiconductor-containing gas are formed in the reaction space. In preferable embodiments of the invention, plasma-excited species and thermally-excited species of the semiconductor-containing gas are formed simultaneously. The substrate is brought in contact 250 with the plasma-excited species and thermally-excited species of the semiconductor-containing gas to form a semiconductor-containing thin film on the substrate. In a preferable embodiment of the invention, the substrate is moved through the reaction space while the semiconductor-containing thin film is formed on the substrate. Upon termination of deposition, the flow of semiconductor-containing gas into the reaction space may be terminated, power to a plasma-generating apparatus and hot wire unit may be terminated, and the pressure in the reaction space may be decreased using a pumping system in fluid communication with the reaction chamber.

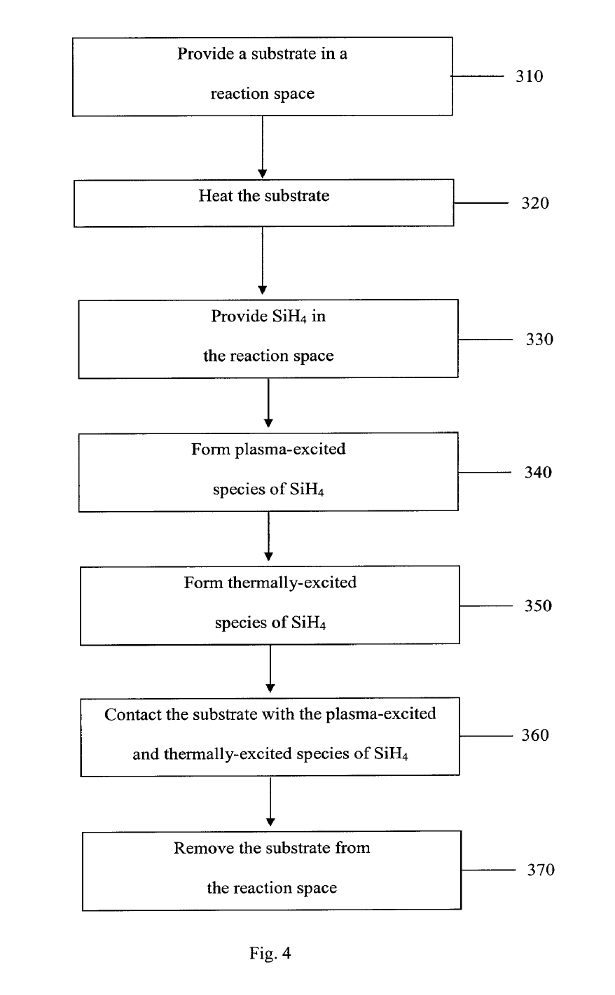

FIG. 4 illustrates a process flow diagram for forming a silicon-containing thin film from silane (SiH₄), in accordance with an embodiment of the invention. A substrate upon which deposition is desired can be provided 310 in a reaction space of a reaction chamber (or reaction system). The substrate can be heated 320 to a reaction temperature with the aid of one or more heating elements in close proximity to the substrate.

Next, SiH₄ is provided 330 into the reaction space. SiH₄ may be provided into the reaction space with the aid of a carrier gas, such as H₂(g). SiH₄ may be directed into the reaction space through one or more plasma-generating apparatuses in the reaction space. Alternatively, SiH₄ may be directed into the reaction space through substrate inlet ports of the reaction chamber.

Next, power is provided 340 to one or more plasma-generating apparatuses in the reaction space to form plasma-excited species of SiH₄. Any source of power for forming plasma-excited species of SiH₄ can be used. For example, RF or VHF power maybe used. Power is also provided 350 to one or more hot wire units to form thermally-excited species of SiH₄. In some cases, power may be provided to the one or more hot wire units via a direct current (DC) power supply in electrical contact with the one or more hot wire units. Application of DC power causes the temperature of the hot wire units to increase. In some cases, power may be supplied to the one or more plasma-generating apparatuses and the one or more hot wire units at essentially the same time SiH₄ is provided into the reaction space.

Next, the substrate is brought in contact 360 with the plasma-excited and thermally-excited species of SiH₄ to deposit a silicon-containing thin film on the substrate. In a preferable embodiment of the invention, the substrate is moved through the reaction space at a predetermined rate during thin film deposition. For instance, the substrate may be disposed on a substrate roll that is directed into the reaction space through a substrate inlet port of the reaction chamber. After a predetermined time, the substrate is removed 370 from the reaction space. In a preferable embodiment of the invention, the substrate is removed as the substrate roll is directed out of the reaction space through a substrate outlet port of the reaction chamber.

In another aspect of the invention, a hybrid CVD apparatus comprises reaction space including a plasma-generating apparatus and a plurality of hot wire units. The plasma-generating may be a showerhead configured to deliver a vapor phase chemical to the reaction space.

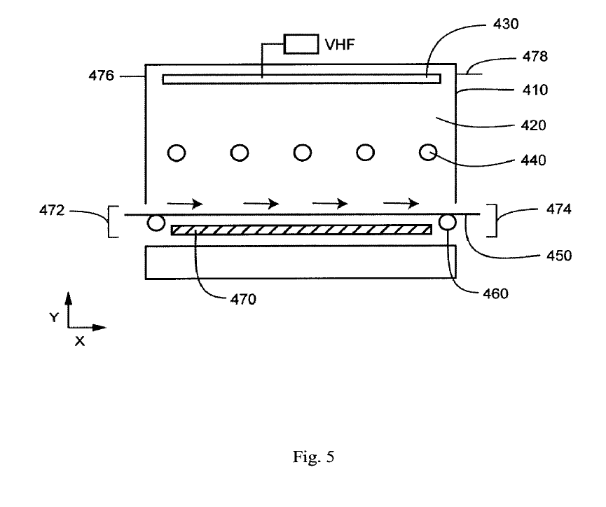

FIG. 5 illustrates a reaction chamber 410 comprising a reaction space 420, a plasma-generating apparatus 430, a plurality of hot wire units 440, a substrate 450 and substrate support members 460. The plasma-generating apparatus 430 may be a plate or a box, such as a showerhead. Each of the hot wire units 440 may comprise one or more filaments. The hot wire units 440, as illustrated, are equidistant from the substrate 450. However, it will be appreciated that the hot wire units 440 need not be equidistant from the substrate 450. For example, a subset of the hot wire units may be a first distance away from the substrate 450, while another subset of the hot wire units may be a second distance away from the substrate 450, wherein the first distance is not equal to the second distance.

The reaction chamber 410 may include a heater 470 near the substrate 450. The heater 470 may be configured to heat the substrate 450 during thin film deposition. The heater 470 may be configured to provide heat via radiative heating or conductive heating. If radiative heating is employed, the heater 470 may be a filament (e.g., tungsten, tantalum, or molybdenum filament), a heated plate, or a halogen lamp in close proximity to a bottom surface of the substrate 450. The heater 470 may be a heating apparatus comprising a plurality of heating units, such as a heating apparatus comprising a plurality of heating filaments evenly dispersed below the substrate 450. If conductive heating is employed, the heater 470 may be a resistive heating unit thermally coupled to the substrate 450. Thermal coupling may be accomplished via copper braids, for example. If conductive heating is employed, the heater 470 need not be disposed in the reaction space 430.

With continued reference to FIG. 5, the substrate 450 can enter the reaction space 420 through a substrate inlet port 472 of the reaction chamber 410 and leave the reaction space 420 through a substrate outlet port 474. The substrate support members 460 hold the substrate in a stable plane while allowing longitudinal movement of the substrate 450. In a preferable embodiment of the invention, the substrate 450 moves longitudinally during thin film deposition in the direction of the arrow, as illustrated. In one embodiment of the invention, the substrate support members 460 may include sprockets. The substrate support members 460 may provide longitudinal movement of the substrate 450 with the aid of one or more motors connected to the substrate support members 460.

A vapor phase chemical may be introduced into the reaction space 420 via a gas inlet port 476, and any excess (or unreacted) vapor phase chemical may be removed from the reaction space 420 via a gas outlet port 478. Gas outlet port 478 may be in fluid communication with a vacuum pumping system, including one or more pumps. In another embodiment of the invention, the substrate inlet port 472 can serve as a gas inlet port and the substrate outlet port 474 can serve as a gas outlet port. In yet another embodiment of the invention, a vapor phase chemical may be introduced into the reaction space 420 through the plasma-generating apparatus 430.

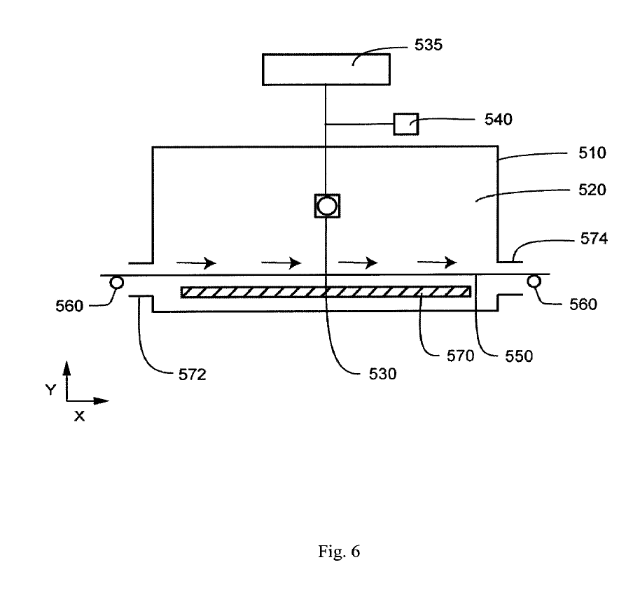

FIG. 6 illustrates a reaction chamber 510 comprising a reaction space 520, in accordance with an embodiment of the invention. The reaction chamber 510 further includes a dual excitation unit 530, which is a combined hot wire unit and plasma-generating apparatus 530. The dual excitation unit 530 is in electrical communication with a plasma power supply 535 for forming plasma-excited species of a vapor phase chemical. The plasma power supply 535 may be an RF or VHF power supply. The dual excitation unit 530 is also in electrical communication with a power supply 540 for forming thermally-excited species of the vapor phase chemical. In one embodiment of the invention, the power supply 540 is a DC power supply. In another embodiment of the invention, the DC power supply 540 and the VHF power supply 535 are electrically isolated from one another via a blocking device, such as a direct current (DC) block.

With continued reference to FIG. 6, the reaction chamber 510 further comprises a substrate 550, which can be configured to move in a longitudinal during thin film deposition. In a preferable embodiment of the invention, the substrate 550 is permitted to move in a lateral direction during thin film deposition. Substrate support members 560 provide support to the substrate 550. The substrate 550 may be a single block, or a roll of substrate or a coil of substrate as part of a roll-to-roll mechanism. Although the substrate support members 560, as illustrated, are disposed outside the reaction space 520, the substrate support members 560 may be disposed in the reaction space 520. The substrate support members 560 may be rollers. The substrate support members 560 may hold the substrate 550 in a stable plane while allowing longitudinal movement. In another embodiment of the invention, the substrate support members 560 may include sprockets for providing longitudinal movement of the substrate 550 during thin film deposition. The substrate support members 560 may be connected to one or more motors, such as, e.g., electrical motors.

Accordingly, in the illustrated embodiment of FIG. 6, a plasma-generating apparatus and a hot wire unit, such as the plasma-generating unit 30 and hot wire unit 40 of FIG. 1, are combined into a single structure but remain functionally distinct. That is, the dual excitation unit 530 of FIG. 6 permits the simultaneous formation of plasma-excited species of a vapor phase chemical and thermally-excited species of the vapor phase chemical. While one dual excitation unit 530 is illustrated, the reaction chamber 510 may include a plurality of dual excitation units 530. For example, the reaction chamber 510 may include three dual excitation units. Additionally, the reaction chamber 510 may include a dual excitation unit 530 in addition to one or more plasma-generating apparatuses and/or one or more hot wire units.

With continued reference to FIG. 6, the substrate 550 enter the reaction space 520 through a substrate inlet port 572 and leave the reaction space 520 through a substrate outlet port 574. A vapor phase chemical may be directed into the reaction space 520 via a gas inlet port, and any excess (or unreacted) vapor phase chemical may be removed from the reaction space 520 via a gas outlet port. In one embodiment of the invention, the substrate inlet port 572 and outlet port 574 may serve as gas inlet and gas outlet ports, respectively. In another embodiment of the invention, a vapor phase chemical is directed into the reaction space via the dual excitation unit 530. For example, the dual excitation unit 530 may be a showerhead having one or more gas inlet tubes.

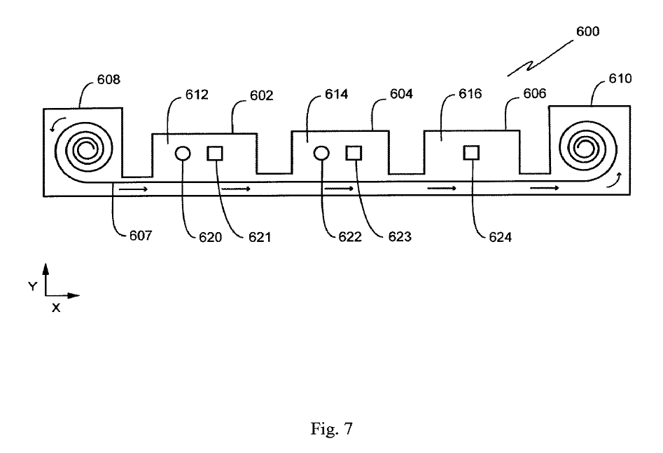

FIG. 7 illustrates a vapor phase deposition system 600 having a first reaction chamber 602, a second reaction chamber 604 and a third reaction chamber 606. The substrate 607 is supplied from a payout chamber 608 and guided through the first reaction chamber 602, the second reaction chamber 604 and the third reaction chamber 606. The substrate 607 is collected in a take-up chamber 610. Collectively, the payout chamber 608 and the take-up chamber 610 can at least partially define a substrate support system, such as any one of the substrate support systems described above. In one embodiment of the invention, the substrate support system can be a roll-to-roll substrate support system.

With continue reference to FIG. 7, the payout chamber 608 and the take-up chamber 610 can each include a motorized member (or unit) for permitting lateral movement of the substrate 607 during deposition. In an embodiment of the invention, at least one of the payout chamber 608 and the take-up chamber 610 transports the substrate in a longitudinal (or lateral) direction during thin film deposition. While the vapor phase deposition system 600 comprises the payout chamber 608 and a take-up chamber 610, it will be appreciated that the vapor phase deposition system 600 can include only one of the payout chamber 608 and the take-up chamber 610 without the other. For example, the vapor phase deposition system 600 can include the payout chamber 608 without the take-up chamber 610.

With continued reference to FIG. 7, the first reaction chamber 602 comprises a first reaction space 612; the second reaction chamber 604 comprises a second reaction space 614; and the third reaction chamber 606 comprises a third reaction space 616. The first reaction chamber 602 and the second reaction chamber 604 are each configured for hybrid CVD; the third reaction chamber 606 is configured for PECVD, HWCVD or hybrid CVD. In the illustrated embodiment, the third reaction chamber 606 is configured for PECVD.

The first reaction chamber 602 comprises a first hot wire unit 620 and a first plasma-generating apparatus 621; the second reaction chamber 604 comprises a second hot wire unit 622 and a second plasma-generating apparatus 623; and the third reaction chamber 606 comprises a third plasma-generating apparatus 624. Each of the first reaction chamber 602, second reaction chamber 604 and third reaction chamber 606 may include a substrate heating element configured to heat the substrate 607.

With continued reference to FIG. 7, the vapor phase deposition system 600 may include a vacuum pumping system to provide a vacuum in the first reaction chamber 602, second reaction chamber 604 and third reaction chamber 606. Additionally, one or more vapor phase chemicals may be provided in the reaction spaces 612, 614 and 616 via gas inlet ports of each of the reaction chambers 602, 604 and 606. In one embodiment of the invention, one or more vapor phase chemicals may be provided in each of the reaction spaces 612, 614 and 616 through the plasma-generating apparatuses 621, 623 and 624 of each of the reaction chambers 602, 604 and 606, respectively.

With continued reference to FIG. 7, the vapor phase deposition system 600 is configured for successive, layer-by-layer deposition. As a portion of the substrate 607 is moved through each of the reaction chambers 602, 604 and 606, the portion of the substrate 607 may be contacted with plasma- and thermally-excited species of a particular vapor phase chemical to form a thin film layer having a particular composition. For example, during thin film deposition, the first reaction space 612 may be provided with one or more vapor phase chemicals suitable for forming an n-type semiconductor-containing layer; the second reaction space 614 may be provided with one or more vapor phase chemicals suitable for forming an intrinsic semiconductor-containing layer; and the third reaction space 616 may be provided with one or more vapor phase chemicals suitable for forming a p-type semiconductor-containing layer. For instance, SiH₄ and PH₃ may be provided in the first reaction space 612 with an H₂ carrier gas; SiH₄ may be provided in the second reaction space 614 with the aid of an H₂ carrier gas; and SiH₄ and BF₃ may be provided in the third reaction space 616 with the aid of an H₂ carrier gas. Accordingly, a portion of the substrate 607 passing through each of the reaction chambers 602, 604 and 606 in series can be coated with an n-i-p semiconductor structure.

With continued reference to FIG. 7, while the vapor phase deposition system 600 includes three reaction chambers 602, 604 and 606, it will be appreciated that the vapor phase deposition system 600 can include any plurality of reaction chambers. In embodiments of the invention, the vapor phase deposition system 600 can include 2, 3, 4, 5, 6, 7, 8, 9, or 10 reaction chambers. In one embodiment of the invention, the vapor phase deposition system 600 can includes two reaction chambers. In another embodiment of the invention, the vapor phase deposition system 600 can include four reaction chambers.

Each of the reaction chambers 602, 604 and 606 of the vapor phase deposition system 600 may be substantially sealed (e.g., hermetically sealed or blocked) from the other reaction chambers such that a vapor phase chemical provided in one reaction space does not come in contact with a portion of the substrate 607 in another reaction space. For example, the first reaction chamber 602 may be substantially sealed so as to prevent a vapor phase chemical in the first reaction space 612 from entering the second reaction space 614. In an embodiment of the invention, a vapor phase chemical, such as either an inert species or gas (e.g., He, Ar), a carrier gas (e.g., H₂), or a reactive species or gas (e.g., SiH₄) for forming a thin film on a substrate, can be introduced between the substrate outlet port of one reaction chamber and the substrate inlet port of an adjacent reaction chamber to substantially block or prevent the transport of one or more vapor phase chemicals from one reaction chamber to an adjacent reaction chamber.

With continued reference to FIG. 7, the first reaction chamber 602 and the second reaction chamber 604 can each comprise a dual excitation unit, such as the dual excitation unit 530 of FIG. 6. Further, while the plasma-generating apparatuses 621 and 623 and the hot wire units 620 and 622 are disposed as illustrated (i.e., in a side-by-side configuration), the first reaction chamber 602 and the second reaction chamber 604 can include any number and configuration of plasma-generating apparatuses and hot wire units. As an example, the first reaction chamber 602 may include a plasma showerhead disposed above one or more hot wire units.

### Example 1

A 10-foot long reaction chamber, such as the reaction chamber 110 of FIG. 2, is provided. The reaction chamber comprises a plurality of plasma-generating apparatuses and a plurality of hot wire units. The plasma-generating apparatuses are plasma electrodes; the hot wire units are filaments. The spacing between the substrate and the plasma electrodes is 20 mm; the spacing between two consecutive filaments is 40 mm; the spacing between two consecutive plasma electrodes is 40 mm; and the spacing between adjacent plasma electrodes and filaments is 20 mm. The filaments are heated by an electric current to a temperature of about 1850° C. Plasma power is provided to the plasma electrodes by VHF power source. Plasma power is adjusted such that the average power is about 25 W per 100 cm² of substrate area. The substrate is about 36″ wide and moves at a speed of about 15 feet per minute through the reaction chamber. The web is heated radiatively by heated plates placed parallel to it, 5 mm away. A mixture of vapor phase chemicals (or precursor gases) comprising silane (SiH₄) and hydrogen (H₂) in a ratio of about 1:100 is provided into the reaction chamber to commence vapor phase deposition of an intrinsic silicon thin film.

### Example 2

A vapor phase deposition system, such as the vapor deposition system 600 of FIG. 7, comprises three reaction chambers connected in series. Each of the reaction chambers is about 10 feet long. A first and second reaction chamber are configured for hybrid CVD (i.e., they both have plasma electrodes and filaments); a third reaction chamber is configured for PECVD (i.e., it only has a plasma electrode). Vapor phase chemicals are provided in the reaction chambers. A vapor phase mixture of silane, hydrogen and phosphine (PH₃) in a ratio of about 1:100:1 is provided in the first reaction chamber; a vapor phase mixture of silane and hydrogen in a ratio of about 1:100 is provided in the second reaction chamber; and a vapor phase mixture of silane, hydrogen and diborane (B₂H₆) in a ratio of about 1:100:1 is provided in the third reaction chamber. The spacing between the substrate and plasma electrodes in each of the reaction chambers is 20 mm. The spacing between two consecutive filaments is 40 mm, the spacing between two consecutive plasma electrodes is also 40 mm and the spacing between adjacent plasma electrodes and HWCVD filaments is 20 mm. Each reaction chamber includes an array of 50 electrodes for plasma generating as well as an array of 50 filaments for thermal decomposition of vapor phase chemicals. Electric current is passed through the filaments such that they are heated to a temperature of about 1850° C. VHF power is applied to the plasma electrodes at an average power of about 25 W per 100 cm² of substrate area. The substrate is 36″ wide and moves in a roll-to-roll fashion at a speed of 15 feet per minute through the reaction chambers. The substrate is heated radiatively by heated plates placed parallel to the substrate, 5 mm away from a bottom surface of the substrate. An n-i-p stack is thus formed: an n-type silicon layer is formed using the first reaction chamber; an intrinsic silicon layer is formed using the second chamber; and a p-type silicon layer is formed using the third chamber.

### Example 3

A reaction chamber similar to that shown in FIG. 5 is provided. The reaction chamber comprises a single, long plasma-generating apparatus that is a plasma electrode. The reaction chamber further comprises hot wire units that are filaments. The filaments are placed about 10 mm away from the plasma electrode and in a plane parallel to a surface of the plasma electrode. The spacing between the filaments is about 40 mm. A plane comprising the filaments is about 20 mm away from a top surface of the substrate. The plasma electrode is disposed above the filaments; it is further away from the substrate than the filaments. A mixture of vapor phase chemicals comprising silane and hydrogen in a ratio of about 1:100 is provided into the reaction chamber. The pressure of the chamber is maintained at about 50 millitorr. Electric current is passed through the filaments such that they are heated to a temperature of about 1800° C. VHF power at 81.36 MHz frequency is applied to the plasma electrode. The substrate is provided via a substrate web that is about 36″ wide and is radiatively maintained at a temperature of about 400° C. during deposition of an intrinsic silicon thin film. Each reaction chamber includes 3 large-area plate-electrodes for plasma generating as well as an array of 50 filaments for thermal decomposition of vapor phase chemicals.

### Example 4

A reaction chamber similar to that shown in FIG. 6 is provided. The reaction chamber comprises a dual excitation unit comprising a plurality of filaments formed of tungsten. The filaments are placed in a single plane parallel to a top surface of the substrate, disposed about 25 mm away from the top surface of the substrate. The substrate moves through a reaction space of the reaction chamber at a speed of about 10 feet per minute. The reaction chamber has a chamber pressure of the chamber that is maintained at about 50 millitorr using a vacuum pumping system. The filaments are heated to a temperature of about 1850° C. by passing current through the filaments using a DC power source. Plasma power provided using a VHF power source at about 40.68 MHz frequency that is superimposed on the filaments through a DC blocking circuit. A mixture of vapor phase chemicals comprising silane and hydrogen in a ratio of about 1:100 is provided into the reaction chamber to commence deposition of an intrinsic silicon thin film. The total film (or thin film) thickness can be between about 10 nanometers (“nm”) and about 20 micrometers (“microns”), or between about 100 nm and about 10 microns, or between about 0.1 microns and about 5 microns.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of embodiments of the invention herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A system for depositing a thin film over a substrate, comprising:
a reaction space;
a substrate support member configured to permit movement of a substrate in a longitudinal direction;
a plasma-generating apparatus disposed in the reaction space and configured to form plasma-excited species of a vapor phase chemical; and
a filament disposed in the reaction space and configured to heat and decompose a vapor phase chemical.

2. The system of claim 1, wherein the plasma-generating apparatus is electrically isolated from one or more walls of the reaction space.

3. The system of claim 1, wherein the plasma-generating apparatus is configured to provide the vapor phase chemical into the reaction space.

4. The system of claim 1, further comprising one or more heating elements configured to heat the substrate during vapor phase deposition.

5. The system of claim 4, wherein the one or more heating elements are disposed proximate the substrate on a side of the substrate opposite the filament and the plasma-generating apparatus.

6. The system of claim 1, wherein the plasma-generating apparatus is proximate the filament.

7. The system of claim 1, further comprising an additional filament disposed in the reaction space and proximate the plasma-generating apparatus.

8. The system of claim 1, further comprising an additional plasma-generating apparatus disposed in the reaction space and proximate the filament.

9. The system of claim 1, further comprising a vacuum system for providing a vacuum in the reaction space.

10. The system of claim 1, wherein the plasma-generating apparatus is electrically coupled to a radiofrequency (RF) power supply.

11. The system of claim 1, wherein the plasma-generating apparatus is electrically coupled to a very high frequency (VHF) power supply.

12. The system of claim 1, further comprising at least one of a payout chamber and a take-up chamber to transport the substrate in a longitudinal direction during thin film deposition.

13. The system of claim 1, further comprising a plurality of filaments or a plurality of plasma-generating apparatuses.

14. The system of claim 1, wherein the filament is closer to the substrate than the plasma-generating apparatus.

15. The system of claim 1, further comprising an additional reaction space proximate the reaction space, the additional reaction space comprising:
a plasma-generating apparatus disposed in the additional reaction space and configured to form plasma-excited species of a vapor phase chemical; and
a filament disposed in the additional reaction space and configured to heat and decompose a vapor phase chemical.

16. A thin film deposition chamber, comprising:
a filament capable of being heated to 1500° C. or higher;
an electrode to form and maintain a plasma for thin film deposition; and
a substrate support member configured to permit movement of a substrate in a longitudinal direction.

17. A thin film deposition chamber, comprising:
a plurality of plasma electrodes;
a plurality of filaments configured to heat and decompose a vapor phase chemical; and
a roller to permit movement of a substrate in a longitudinal direction.

18. The thin film deposition chamber of claim 17, wherein the plurality of plasma electrodes and the plurality of filaments are in an alternating configuration.

19. An apparatus for forming a thin film on a substrate, comprising:
a first hot wire unit and a second hot wire unit configured to form thermally-excited species of a vapor phase chemical; and
a first plasma-generating member configured to form plasma-excited species of a vapor phase chemical.

20. A method for depositing a layer of a semiconductor-containing material on a substrate, the method comprising:
providing the substrate in a reaction space;
providing a gas in the reaction space, the gas including a semiconductor-containing chemical;
forming plasma-excited species of the semiconductor-containing chemical in the reaction space;
forming thermally-excited species of the semiconductor-containing chemical in the reaction space; and
contacting the substrate with the plasma-excited species of the semiconductor-containing chemical and the thermally-excited species of the semiconductor-containing chemical while the substrate is moved from a first position to a second position in the reaction space.

21. The method of claim 20, wherein the semiconductor-containing chemical is provided in the reaction space with the aid of a carrier gas.
